(19) United States
(12) Patent Application Publication
(10) Pub. No.: US 2024/0383000 A1
(43) Pub. Date: Nov. 21, 2024

(54) METHOD OF PROCESSING SUBSTRATE AND APPARATUS FOR PROCESSING SUBSTRATE

(71) Applicant: EBARA CORPORATION, Tokyo (JP)

(72) Inventors: Jumpei FUJIKATA, Tokyo (JP); Kazuhito TSUJI, Tokyo (JP)

(21) Appl. No.: 18/598,950

(22) Filed: Mar. 7, 2024

(30) Foreign Application Priority Data
May 19, 2023 (JP) 2023-083193

(51) Int. Cl. B05D 1/02; B05B 12/12; B05B 12/18; B05C 1/00; B05D 1/28; B24B 37/04

(52) U.S. Cl. CPC B05D 1/02; B05B 12/124; B05C 1/006; B05D 1/28; B05B 12/18; B24B 37/042

(57) ABSTRACT

One object is to suppress the surface of a substrate from being scratched in the course of a polishing process. There is provided a method of processing a substrate, comprising: a process of forming a protective film on an outer peripheral part of the substrate including a bevel portion, prior to a process of polishing the substrate, wherein the process of forming the protective film includes applying a protective film material in a liquid form onto the outer peripheral part of the substrate and curing the applied protective film material; and the process of polishing the substrate with the protective film formed on the outer peripheral part thereof.

### CROSS REFERENCE TO RELATED APPLICATION

The present application claims priority to Japanese patent application No. 2023-83193 filed on May 19, 2021. The entire disclosure of Japanese patent application No. 2023-83193 filed on May 19, 2021, including the specification, claims, drawings and abstract is incorporated herein by reference in its entirety.

### TECHNICAL FIELD

The present disclosure relates to a method of processing a substrate and an apparatus for processing a substrate.

### BACKGROUND ART

As described in Japanese Patent No. 3,949,941 (PTL 1), in a semiconductor manufacturing process, an outer peripheral part (an edge portion and a bevel portion) of a substrate (for example, a wafer) may be corroded in the course of an etching process of the substrate. This may cause a damage of the outer peripheral part of the substrate during transfer of the substrate or during processing of the substrate. Furthermore, particles trapped in a corroded location is likely to adversely affect the processing of the substrate in a subsequent process and is thus likely to reduce the yield as a result.

With regard to a film forming process, on the other hand, it is known that a film forming technique with plasma CVD or the like generally used in the semiconductor manufacturing process is likely to form an uneven and unrequired film in the outer peripheral part (the edge portion and the bevel portion) of the substrate. This uneven and unrequired film is likely to adversely affect the processing of the substrate in a subsequent process and is thus likely to reduce the yield as a result. In this manufacturing process, even when a protective film is formed as described in Japanese Patent No. 5,982,383 (PTL 2) or Japanese Unexamined Patent Publication No. 2020-021931 (PTL 3), an uneven and unrequired film is formed on the protective film in the outer peripheral part of the substrate. There is accordingly a need to remove this uneven and unrequired film. For example, Japanese Unexamined Patent Publication No. 2002-305201 (PTL 4) describes a method of covering only a deposited film on a semiconductor element (device forming area) with a resist and removing a deposited film on the outer peripheral part of the substrate by wet etching. Japanese Unexamined Patent Publication No. 2007-281191 (PTL 5) describes a method of lifting off a sacrificial film to remove only a metal film on the outer peripheral part of the substrate, since the conventional wet etching method is insufficient.

The method described in PTL 4 and the method described in PTL 5, however, have an inconvenience that provides and uses a plurality of different chemical solutions according to the types of films to be removed in a manufacturing process using a variety of conductive films, non-conductive films, resin films and the like, such as a semiconductor manufacturing process. Additionally, the removing process is complicated. Furthermore, there is a possibility that the protective film on the outer peripheral part of the substrate is damaged and that the shape of the protective film is varied to vary the shape of the substrate, in the process of removing the unrequired film.

A method of physically polishing and removing the location of corrosion in the outer peripheral part of the substrate or physically polishing and removing the unrequired film on the protective film in the outer peripheral part of the substrate by employing the polishing method of PTL 1 is expected to be effective. This method, however, causes continuous changes in the shape and the outer diameter of the outer peripheral part (the edge portion and the bevel portion) of the substrate in the course of the semiconductor manufacturing process. This varies, for example, the outer diameter of the substrate and is likely to induce an error at the time of transfer of the substrate.

### CITATION LIST

### Patent Literatures

PTL 1: Japanese Patent No. 3,949,941
PTL 2: Japanese Patent No. 5,982,383
PTL 3: Japanese Unexamined Patent Publication No. 2020-021931
PTL 4: Japanese Unexamined Patent Publication No. 2002-305201
PTL 5: Japanese Unexamined Patent Publication No. 2007-281191
PTL 6: Japanese Unexamined Patent Publication No. 2015-188955
PTL 7: Japanese Unexamined Patent Publication No. 2009-050943

### SUMMARY OF INVENTION

### Technical Problem

Such corrosion in the outer peripheral part (the edge portion and the bevel portion) of the substrate or adhesion of an incomplete and unrequired film to the outer peripheral part of the substrate also causes an inconvenience in a polishing process of the substrate. A top ring in a substrate polishing apparatus uses a retainer ring with a view to preventing separation of the substrate during polishing as one purpose. Japanese Unexamined Patent Publication No. 2015-188955 (PTL 6) describes that the substrate comes into contact with an inner wall surface of the retainer ring to cause chipping (deficiency) and that a chipped fragment causes the surface of the substrate to be scratched in the course of top ring stabilization (an operation of adding a polishing step to stabilize the pressure in an air bag (air chamber) of the top ring, prior to a start of actual polishing process). A method of detecting a foreign substance on an inner face of the retainer ring has been proposed as a solution of this problem. This detection can, however, not be performed during polishing. This method accordingly fails to completely prevent the scratches.

Japanese Unexamined Patent Publication No. 2009-050943 (PTL 7) describes that the retainer ring which is generally made of an engineering plastic material is abraded and that a deficient fragment causes micro-scratches on the surface of the substrate when an outer edge part of the substrate comes into contact with the retainer ring. A method of providing the retainer ring with a chamfered part has been proposed as a solution of this problem. This method, however, fails to prevent abrasion of the retainer ring and fails to completely prevent the scratches.

It is easy to imagine that corrosion of the outer peripheral part of the substrate or adhesion of the unrequired film in the outer peripheral part of the substrate causes chipping of the substrate and separation of the incomplete film and causes the surface of the substrate to be more significantly scratched, in such a polishing process of the substrate. It is also easy to imagine that contact of an abraded and thereby sharpened part of the substrate with the retainer ring accelerates abrasion of the retainer ring and is likely to induce a deficiency (fragment) and to cause the occurrence of more scratches.

The object of the present disclosure is to solve at least part of the problems described above. One object of the present disclosure is to suppress the surface of a substrate from being scratched in the course of a polishing process. Another object of the present disclosure is to suppress abrasion of a retainer ring configured to hold the substrate in the course of the polishing process.

### Solution to Problem

According to one aspect of the present disclosure, there is provided a method of processing a substrate, comprising: a process of forming a protective film on an outer peripheral part of the substrate including a bevel portion, prior to a process of polishing the substrate, wherein the process of forming the protective film includes applying a protective film material in a liquid form onto the outer peripheral part of the substrate and curing the applied protective film material; and the process of polishing the substrate with the protective film formed on the outer peripheral part thereof.

### BRIEF DESCRIPTION OF DRAWINGS

FIG. 1 is a plan view illustrating the general configuration of a substrate processing apparatus according to one embodiment;

FIG. 2 is an explanatory diagram illustrating the principle of protection of a substrate outer peripheral part according to one embodiment;

FIG. 3 is schematic diagram illustrating a substrate held by a top ring of a polishing unit;

FIG. 4 is sectional views illustrating the neighborhood of a substrate outer peripheral part with protective films formed therein;

FIG. 5 is a flowchart showing a substrate treatment process;

FIG. 6 is a sectional view illustrating an application unit in a coating module according to one embodiment;

FIG. 7 is a sectional view illustrating the application unit in the coating module according to one embodiment;

FIG. 8 is a sectional view illustrating the application unit in the coating module according to one embodiment;

FIG. 9 is sectional views illustrating the application unit in the coating module according to the embodiment;

FIG. 10 is a perspective view illustrating a configuration example of a nozzle where microtubes are arrayed at a narrow pitch;

FIG. 11 is a sectional view illustrating the configuration example of the nozzle where the microtubes are arrayed at the narrow pitch;

FIG. 12 is sectional views illustrating the application unit in the coating module according to one embodiment;

FIG. 13 is a sectional view illustrating the application unit in the coating module according to one embodiment;

FIG. 14 is an enlarged sectional view illustrating closeup of the periphery of a sponge that comes into contact with a substrate;

FIG. 15 is a sectional view illustrating the principle of application in the application unit according to one embodiment;

FIG. 16 is a sectional view illustrating the application unit in the coating module according to one embodiment;

FIG. 17 is a sectional view illustrating the application unit in the coating module according to one embodiment;

FIG. 18 is a schematic diagram illustrating the schematic configuration of a curing unit;

FIG. 19 is a schematic diagram illustrating the schematic configuration of an application/curing integral unit according to one embodiment;

FIG. 20 is a flowchart showing a protective film forming process according to one embodiment;

FIG. 21 is a sectional view illustrating a peeling unit according to one embodiment;

FIG. 22 is a sectional view illustrating a peeling unit according to another embodiment; and

FIG. 23 is a schematic diagram illustrating the schematic configuration of an application/curing/peeling integral unit according to one embodiment.

### DESCRIPTION OF EMBODIMENTS

The following describes one embodiment of the present disclosure with reference to the drawings. In the respective embodiments described below, identical or equivalent members are expressed by identical reference signs with omission of duplicated description. In the description hereof, the expressions such as “upper” or “upward”, “lower” or “downward”, “left” or “leftward” and “right” and “rightward” are used. These expressions indicate the positions, the orientations, and the directions on the sheet surface of the illustrated drawings for the purpose of explanation, and these positions, orientations and directions may be different from those in the actual arrangement, for example, when using the apparatus. In the description hereof, the term “suppress/prevent” means “suppress or prevent”.

### (General Configuration of Substrate Processing Apparatus)

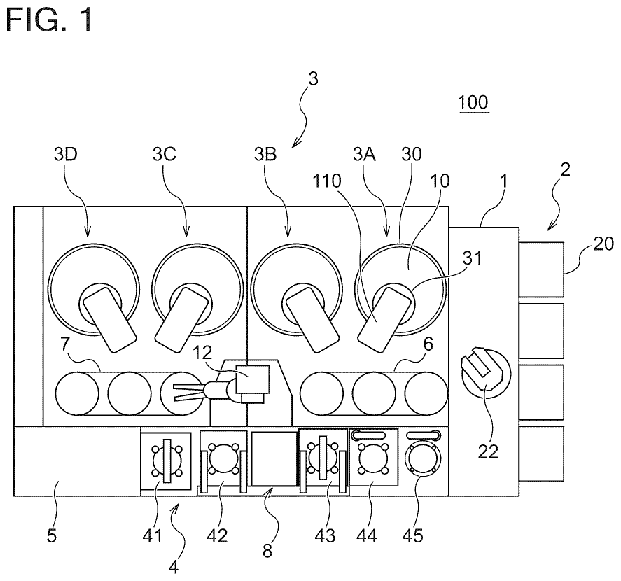

FIG. 1 is a plan view illustrating the general configuration of a substrate processing apparatus 100 according to one embodiment. This embodiment is described with a wafer referring to as an example of a substrate that is a member to be processed. The present disclosure is, however, applicable to any substrate other than the wafer (for example, a glass substrate or a printed circuit board). The member to be processed may be a substrate in a circular shape, in a rectangular or other polygonal shape, or in any other arbitrary shape. The substrate is, for example, a wafer with semiconductor devices, optical elements, MEMS and the like formed thereon. The substrate may, however, be a substrate with other types of devices formed thereon. The substrate may be a silicon substrate (including a substrate made of silicon as a material and a composite silicon such as an SOI substrate with silicon on a surface thereof), a compound semiconductor substrate, or a substrate made of any arbitrary material.

FIG. 1 is a plan view illustrating the general configuration of the substrate processing apparatus 100 according to one embodiment of the present disclosure. As shown in FIG. 1, this substrate processing apparatus 100 has a housing 1 in a substantially rectangular shape and includes a loading/unloading module 2, a polishing module 3, a cleaning module 4, and a coating module 8 that are provided inside of the housing 1. These respective loading/unloading module 2, polishing module 3, cleaning module 4 and coating module 8 are individually assembled and are individually evacuated. The substrate processing apparatus 100 also includes a controller 5 configured to control the respective devices in the apparatus and thereby control substrate processing operations. The controller 5 includes a CPU configured to establish communication with a storage device (a volatile memory, a non-volatile memory or the like) inside of the controller or outside of the controller. The storage device stores, for example, a variety of programs and parameters relating to the control of the substrate processing operations.

The loading/unloading module 2 includes not less than two (four according to the embodiment) front loading portions 20 where wafer cassettes with a large number of wafers (substrates) stocked therein are placed on. These front loading portions 20 are placed adjacent to the housing 1 and are arrayed along a width direction (a direction perpendicular to a longitudinal direction) of the substrate processing apparatus 100. The front loading portions 20 are configured such that open cassettes, SMIF (Standard Manufacturing Interface) pods or FOUPs (Front Opening Unified Pods) are mountable thereon. Each of SMIF and FOUP herein denotes a sealed container that is configured such that a wafer cassette is placed inside thereof and that is covered by partition walls to maintain an environment independent of an external space.

A traveling mechanism (not shown) is laid along the array of the front loading portions 20 in the loading/unloading module 2, and a transfer robot (loader) 22 configured to be movable along a direction of array of the wafer cassettes is placed on this traveling mechanism. The transfer robot 22 moves on the traveling mechanism so as to gain access to wafer cassettes mounted on the front loading portions 20. The transfer robot 22 has two hands on an upper side and a lower side and selectively uses the upper-side hand and the lower side hand or more specifically uses the upper-side hand to return a processed substrate to a wafer cassette and uses the lower-side hand to take out a substrate to be processed or an unprocessed substrate from a wafer cassette. Furthermore, the lower-side hand of the transfer robot 22 is configured to rotate around a shaft center thereof such as to invert the substrate.

The loading/unloading module 2 is an area required to be maintained in the cleanest state, so that the inside of the loading/unloading module 2 is always kept at a higher pressure than the pressures of all of the polishing module 3, the cleaning module 4, the coating module 8, and the outside of the substrate processing apparatus 100. The polishing module 3 uses slurry as a polishing solution and is a dirtiest area. Accordingly, a negative pressure is provided inside of the polishing module 3, and the internal pressure of the polishing module 3 is kept lower than the internal pressure of the cleaning module 4. The loading/unloading module 2 is provided with a filter fan unit (not shown) that has a clean air filter, such as an HEPA filter, a ULPA filter or a chemical filter, and that continuously blows off the clean air with removal of particles, toxic vapors and toxic gases.

The polishing module 3 is an area where polishing (planarization) of the substrate is performed, and includes a polishing unit 3A, a polishing unit 3B, a polishing unit 3C and a polishing unit 3D. Part or all of the polishing unit 3A, the polishing unit 3B, the polishing unit 3C and the polishing unit 3D are polishing units configured to perform an identical type of or different types of polishing (planarization) processes.

As shown in FIG. 1, the polishing unit 3A includes a polishing table 30 which a polishing pad 10 having a polishing surface is mounted thereon, and a top ring (substrate holding member) 31 which is attached to a top ring head 110 and which is configured to hold a substrate W and polish the substrate W with pressing the substrate W against the polishing pad 10 on the polishing table 30. The polishing unit 3A may further include a polishing solution supplying nozzle configured to supply a polishing solution and a dressing liquid (for example, pure water such as DIW) to the polish pad 10, a dresser configured to perform dressing of the polishing surface of the polishing pad 10, and an atomizer configured to atomize a fluid mixture of a liquid (for example, pure water such as DIW) and a gas (for example, nitrogen gas), or atomize a liquid (for example, pure water such as DIW) and spray the atomized fluid mixture or the atomized liquid onto the polishing surface. The polishing unit 3B, the polishing unit 3C and the polishing unit 3D are similarly configured.

In the illustrated example, the cleaning module 4 includes a cleaning unit 41, a cleaning unit 42, a cleaning unit 43, a cleaning unit 44 and a drying unit 45. Part or all of the cleaning unit 41, the cleaning unit 42, the cleaning unit 43 and the cleaning unit 44 are units configured to perform an identical type of or different types of cleaning processes. The drying unit 45 is a unit configured to perform a drying process of the substrate W.

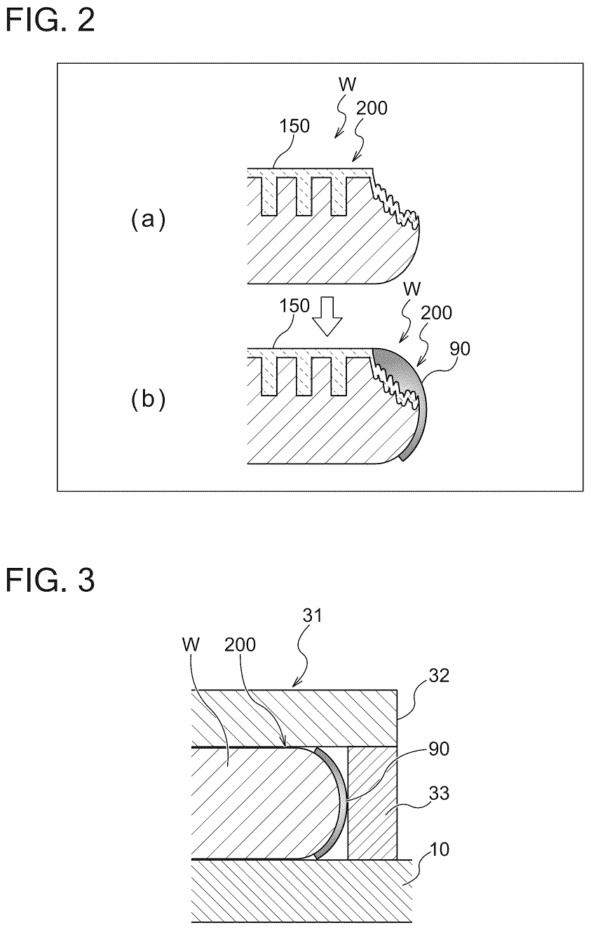

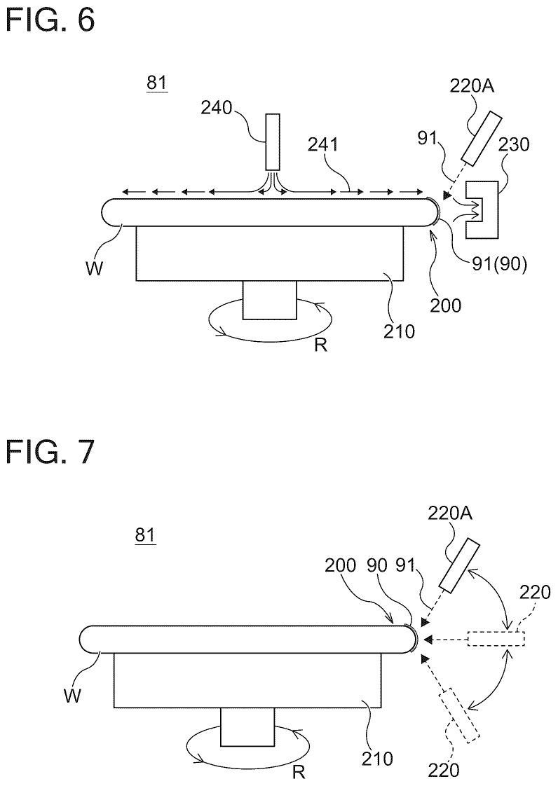

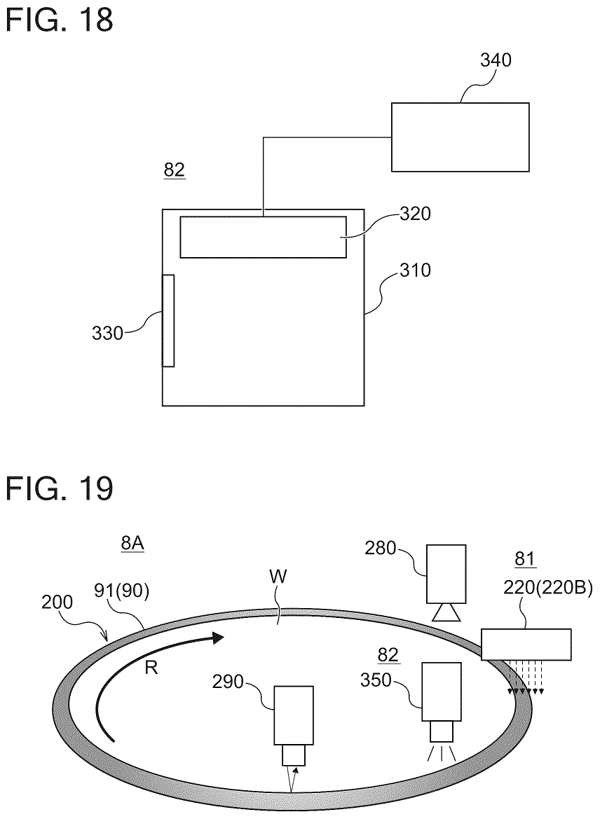

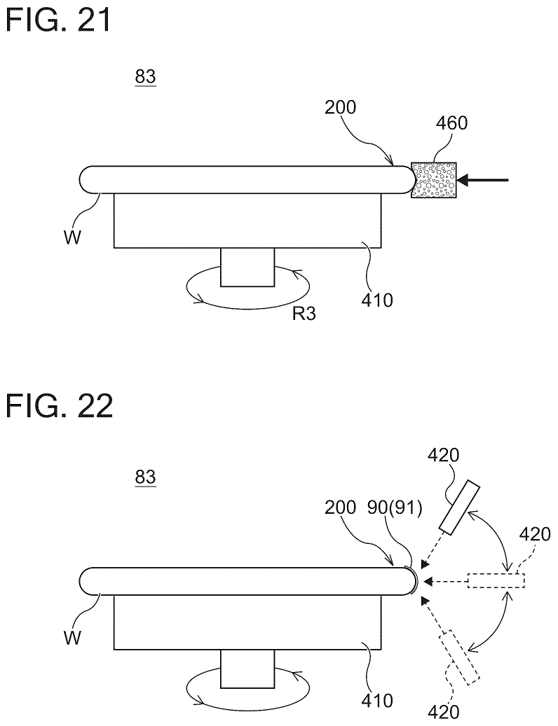

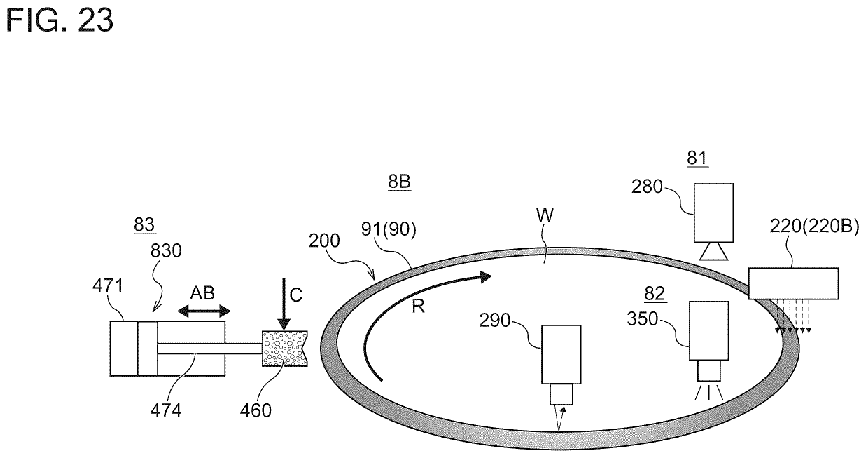

The coating module 8 includes an application unit 81 (shown in FIG. 6 to FIG. 17, FIG. 19 and FIG. 23), a curing unit 82 (shown in FIG. 18, FIG. 19, and FIG. 23) and a peeling unit 83 (shown in FIG. 21 to FIG. 23), which are units configured to form a protective film 90 (shown in FIG. 2) on an outer peripheral part 200 of the substrate W prior to a polishing process of the substrate W as described later. Part or all of the application unit 81, the curing unit 82 and the peeling unit 83 may be provided as one integral unit, or the application unit 81, the curing unit 82 and the peeling unit 83 may be respectively provided as separate units. According to another embodiment, part or all of the application unit 81, the curing unit 82 and the peeling unit 83 may be provided as a separate body outside of the substrate processing apparatus 100.

A material having a lower hardness than the hardness of the material of the substrate W (i.e., a material softer than the material of the substrate W) is used for a coating material (a protective film material 91) that is a material of the protective film 90. The hardness of the protective film material 91 herein means the hardness of the protective film material 91 in the state after being applied in a liquid state (in a liquid form: including a gel form) on the substrate and subsequently being cured/dried (i.e., the hardness of the protective film 90). In other words, the hardness of the protective film 90 is selected to be lower than the hardness of the substrate W (i.e., the protective film 90 is selected to be softer than the substrate W). This suppresses or prevents abrasion and deficiency of a retainer ring that is used to hold the substrate W. For example, a resin (a polyimide, a water-soluble PVA, an SOG (Spin on Glass) material generally used in manufacturing semiconductors or a resist material) may be employed for such a material of the protective film 90/the protective film material 91.

A linear transporter 6 is placed adjacent to the polishing unit 3A and the polishing unit 3B. This linear transporter 6 is a mechanism configured to transfer the substrate W between a plurality of transfer positions (three transfer portions in the illustrated example) along a direction in which the polishing unit 3A and the polishing unit 3B are arrayed. The linear transporter 6 receives the substrate W from the transfer robot 22 and transfers the substrate W between the plurality of transfer positions. The substrate W is handed over between the linear transporter 6 and the polishing unit 3A or the polishing unit 3B. By a swing action of the top ring head 110, the top ring 31 of the polishing unit 3A receives the substrate W placed at a predetermined transfer position of the linear transporter 6, moves the substrate W to a polishing position, and returns the polished substrate W to a transfer position identical with or different from the predetermined transfer position of the linear transporter 6. The substrate W is handed over between the polishing unit 3B and the linear transporter 6 in a similar manner.

A swing transporter 12 is placed between the linear transporter 6, the linear transporter 7, the cleaning module 4, and the coating module 8. This swing transporter 12 has a hand that is movable between a transfer position of the linear transporter 6 and a transfer position of the linear transporter 7. The substrate is handed over from the linear transporter 6 to the linear transporter 7 by the swing transporter 12.

The linear transporter 7 is placed adjacent to the polishing unit 3C and the polishing unit 3D. This linear transporter 7 is a mechanism configured to transfer the substrate W between a plurality of transfer positions (three transfer portions in the illustrated example) along a direction in which the polishing unit 3C and the polishing unit 3D are arrayed. The linear transporter 7 receives the substrate W from the swing transporter 12 and transfers the substrate W between the plurality of transfer positions. The substrate W is handed over between the linear transporter 7 and the polishing unit 3C or the polishing unit 3D. By a swing action of the top ring head 110, the top ring 31 of the polishing unit 3C receives the substrate W placed at a predetermined transfer position of the linear transporter 7, moves the substrate W to a polishing position, and returns the polished substrate W to a transfer position identical with or different from the predetermined transfer position of the linear transporter 7. The substrate W is handed over between the polishing unit 3D and the linear transporter 7 in a similar manner.

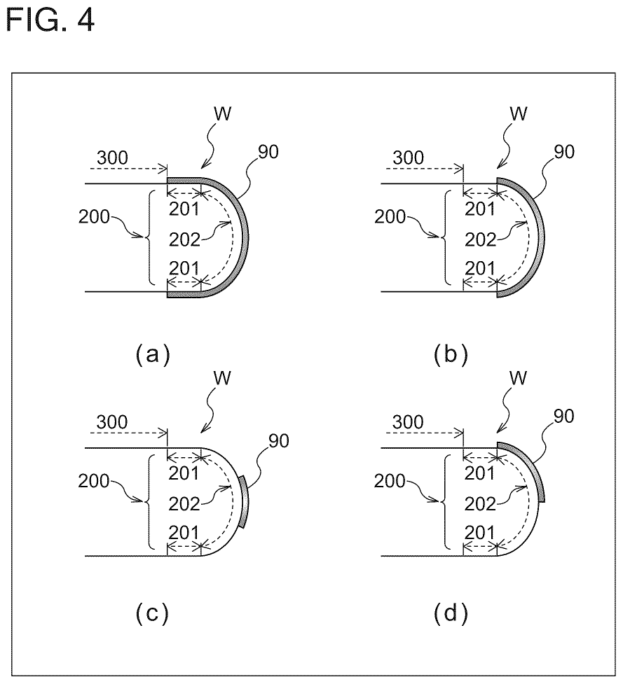

According to this embodiment, the substrate W is transferred from the transfer robot 22 of the loading/unloading module 2 and is carried into the coating module 8 via the linear transporter 6 and the swing transporter 12. The coating module 8 applies and cures the protective film material 91 on the outer peripheral part 200 of the substrate W to form the protective film 90 (for example, as shown in FIG. 4 and FIG. 6), prior to the polishing process of the substrate W. The substrate W with the protective film 90 formed on the outer peripheral part 200 is then transferred to the polishing unit 3A and/or the polishing unit 3B via the swing transporter 12 and the linear transporter 6 to be subjected to the polishing process. The substrate W subjected to the polishing process in the polishing unit 3A and/or the polishing unit 3B is subjected to further polishing in the polishing unit 3C and/or the polishing unit 3D or is not subjected to further polishing in the polishing unit 3C and/or the polishing unit 3D and is again transferred to the coating module 8 via the swing transporter 12. The coating module 8 then performs a process of peeling off the protective film 90 from the substrate W. The substrate W after peel-off of the protective film 90 is sequentially cleaned by the cleaning units 41 to 44, is dried by the drying unit 45, is transferred to the transfer robot 22 and is returned to a cassette of the front loading portion 20.

The configuration of the substrate processing apparatus 100 described above is only illustrative, and another configuration may be employed for the substrate processing apparatus 100.

### (Principle of Protection of Substrate Outer Peripheral Part)

FIG. 2 is an explanatory diagram illustrating the principle of protection of a substrate outer peripheral part according to one embodiment. FIG. 3 is schematic diagram illustrating a substrate held by the top ring 31 of the polishing unit. The top ring 31 includes a top ring main body 32 provided with a pressure chamber and the like; and a retainer ring 33 that is a ring-shaped member placed in the periphery of the substrate W on the polishing pad 10 to surround the outer periphery of the substrate W and prevent protrusion of the substrate W. The retainer ring 33 is made of, for example, a resin material such as engineering plastics (PEEK, PPS and the like).

As shown in FIG. 2(a), a film 150 formed in the outer peripheral part 200 (edge portions and a bevel portion) of the substrate W is likely to be incomplete in a semiconductor manufacturing process. For example, as illustrated, the film 150 in the outer peripheral part 200 of the substrate W is likely to have a jagged surface (portion sharpened by corrosion of the substrate). In the case where such a substrate W is held by the top ring 31, the retainer ring 33 of the top ring 31 (shown in FIG. 3) is likely to come into contact with the outer peripheral part 200 of the substrate W and cause chipping that chips part of the substrate W. Such chipping (fragment) of the substrate W is likely to scratch the surface of the substrate W in the course of polishing the substrate W. Furthermore, there is also a possibility that an outer peripheral edge of the substrate W comes into contact with the retainer ring 33 to abrade the retainer ring 33 and thereby cause the chipped fragment to scratch the surface of the substrate W.

The configuration of this embodiment accordingly forms the protective film 90 on the outer peripheral part 200 of the substrate W prior to the polishing process of the substrate W and subsequently causes the substrate W with the protective film 90 formed on the outer peripheral part 200 thereof to be held by the top ring 31. This configuration causes the protective film 90 to work as a shock-absorbing material and suppresses or prevents chipping of the substrate W, as well as abrasion of the retainer ring 33, which may occur when the substrate W comes into contact with the retainer ring 33. Moreover, covering the incomplete film 150 formed in the substrate outer peripheral part with the protective film 90 suppresses or prevents separation of the film 150, which may occur when the substrate W comes into contact with the retainer ring 33. Furthermore, using the protective film 90 that has the lower hardness than the hardness of silicon generally used as the material of the substrate W suppresses or prevents abrasion and deficiency of the retainer ring 33. Peeling off and removing the protective film 90 from the substrate W after the polishing process of the substrate W suppresses or prevents the protective film 90 from affecting a subsequent semiconductor manufacturing process of the substrate W.

FIG. 4 is sectional views illustrating the neighborhood of the substrate outer peripheral part 200 with the protective film 90 formed therein. In the description hereof, as shown in FIG. 4, the outer peripheral part 200 of the substrate W includes edge portions 201 and a bevel portion 202. The bevel portion 202 is a chamfered side face portion of the substrate W, and the edge portions 201 are flat portions on the inner side of the bevel portion 202 in the outer peripheral part 200 of the substrate W. According to this embodiment, an area/range on an inner side of the outer peripheral part 200 of the substrate W is referred to as a center part 300. According to this embodiment, out of a front face and a rear face of the substrate W (an upper face and a lower face in FIG. 4), the center part 300 on the front face is a device forming area. According to another embodiment, the device forming area may be provided on both the front face and the rear face of the substrate W. The outer peripheral part 200 may be defined as an area on an outer side of the device forming area. For example, in the case where the device forming area is provided on the front face of the substrate W, areas of the front face and the rear face of the substrate W corresponding to the device forming area may be specified as the center part 300, and the outer side of the center part 300 on the front face and the rear face of the substrate W may be specified as the outer peripheral part 200. In one example, the outer peripheral part 200 of the substrate W has a width of greater than 0 mm and not greater than 10 mm from an outermost edge of the substrate W along a radial direction of the substrate W.

As shown in FIG. 4, the location where the protective film 90 is formed on the outer peripheral part 200 of the substrate W may be the edge portions 201 and the bevel portion 202 (shown in FIG. 4(a)), only the bevel portion 202 (shown in FIG. 4(b)), only an outermost edge face (shown in FIG. 4(c)), or only the bevel portion 202 on a single side (a polishing surface side) (shown in FIG. 4(d)). The location where the protective film 90 is formed is not limited to these illustrated examples but may be any portion of the outer peripheral part 200 of the substrate W. The location where the protective film 90 is formed on the outer peripheral part 200 of the substrate W may be a location that requires protection or a location that is expected to be sufficient for protection, according to the specifications of the apparatus and the substrate. From the viewpoint of protecting the outer peripheral part 200 of the substrate W, it is preferable that the protective film 90 is formed along the entire circumference of the outer peripheral part 200 of the substrate W.

### (General Flow of Substrate Treatment)

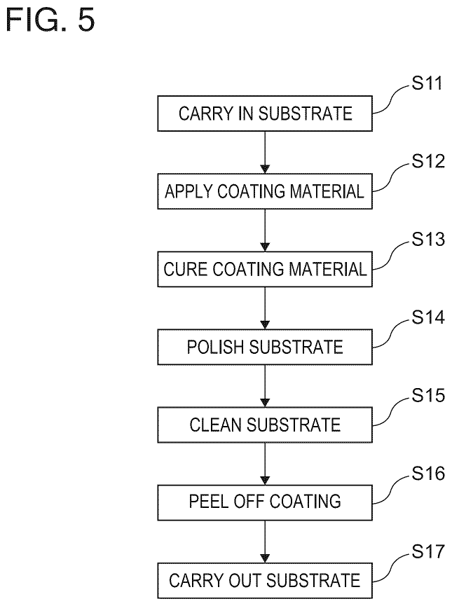

FIG. 5 is a flowchart showing a substrate treatment process in the substrate processing apparatus 100. This treatment process is performed by the controller 5.

At step S11, the substrate W is taken out from a wafer cassette, is transferred along the transfer pathway described above in the substrate processing apparatus 100 to the coating module 8, and is carried into the coating module 8.

At step S12, the protective film material 91 is applied onto the outer peripheral part 200 of the substrate W in the coating module 8.

At step S13, in the coating module 8, a curing process of the protective film material 91 is performed to cure the protective film material 91 and thereby form the protective film 90 on the outer peripheral part 200 of the substrate W. The application of the protective film material (S12) and the curing process of the protective film material 91 (S13) may be performed repeatedly to form the protective film 90 by stacking layers of the protective film materials 91.

At step S14, the substrate W with the protective film 90 formed on the outer peripheral part 200 thereof is transferred to the polishing unit 3A, 3B, 3C and/or 3D to be polished in such a state that the substrate W is held by the top ring 31.

At step S15, the substrate W is cleaned by the cleaning units 41 to 44 and is dried by the drying unit 45 as needed basis.

At step S16, in the coating module 8, a peeling process of the substrate W is performed to peel off the protective film 90 from the substrate W. The peeling process may be performed, prior to the cleaning process (S15).

At step S17, a cleaning process and a drying process are appropriately performed for the substrate W after the peel-off of the protective film, and the substrate W is then carried out.

### (Configuration of Coating Module)

FIG. 6 is a sectional view illustrating the application unit 81 in the coating module 8 according to one embodiment. In the illustrated embodiment, the application unit 81 includes a stage 210 configured to place the substrate W thereon and rotate the substrate W; a nozzle 220A configured to spray the protective film material 91 in the liquid form, which is the material of the protective film 90, onto the outer peripheral part 200 of the substrate W; and a pump (not shown) configured to supply the protective film material 91 to the nozzle 220A. In the description hereof, any nozzles used to spray the protective film material including nozzles of respective embodiments described below may be referred to as the nozzle 220. The application unit 81 may also be provided with a nozzle 240 configured to make a flow of a clean gas (the air, nitrogen or the like) above the substrate W, with a view to preventing the protective film material 91 from being splashed over the surface of the substrate W (on the inner side of the outer peripheral part 200). The nozzle 240 may be placed, for example, above the center of or above the periphery of the center of the substrate W. A duct 230 may further be provided in the outer peripheral part 200 of the substrate W, in order to suck in the protective film material 91 that is not applied on the substrate W but is splashed.

FIG. 7 is a sectional view illustrating the application unit 81 in the coating module 8 according to another embodiment. As shown in FIG. 7, the nozzle 220A may be configured to be movable in a vertical direction in the state that the spray direction of the nozzle 220A faces the outer peripheral part 200 of the substrate W. This configuration facilitates formation of the uniform protective film 90 along the shape of the outer peripheral part 200 of the substrate W. A plurality of nozzles 220A may be provided in the application unit 81. For example, the nozzles 220A may be provided at a plurality of positions (at three different positions in the illustrated example) in the vertical direction of the nozzle 220A illustrated in FIG. 7. The nozzles 220A may be provided at four or more different positions.

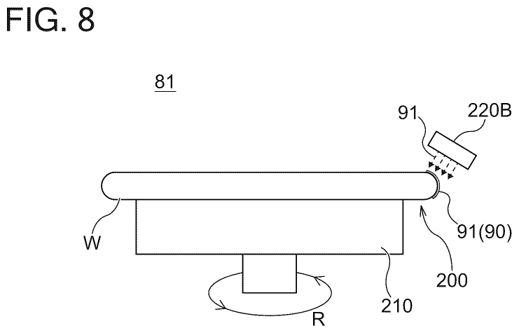

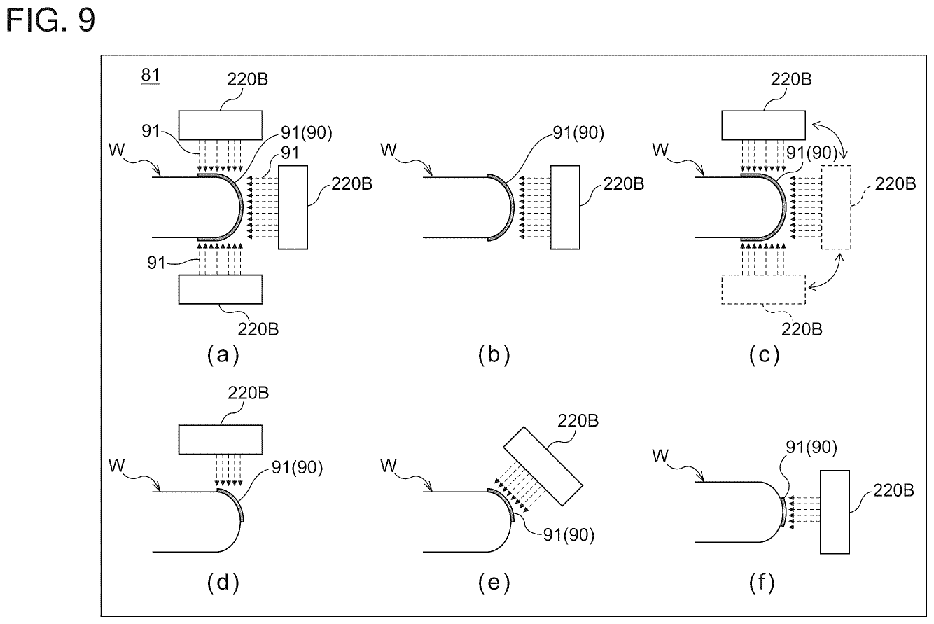

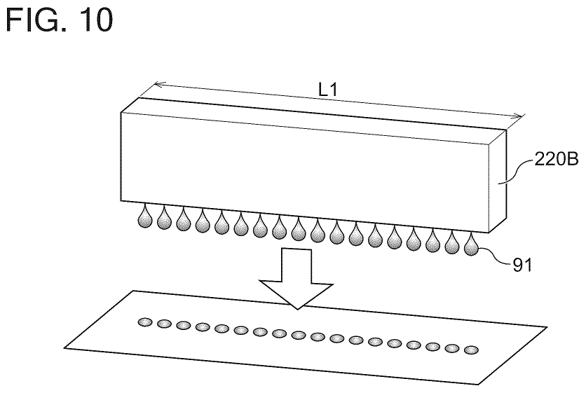

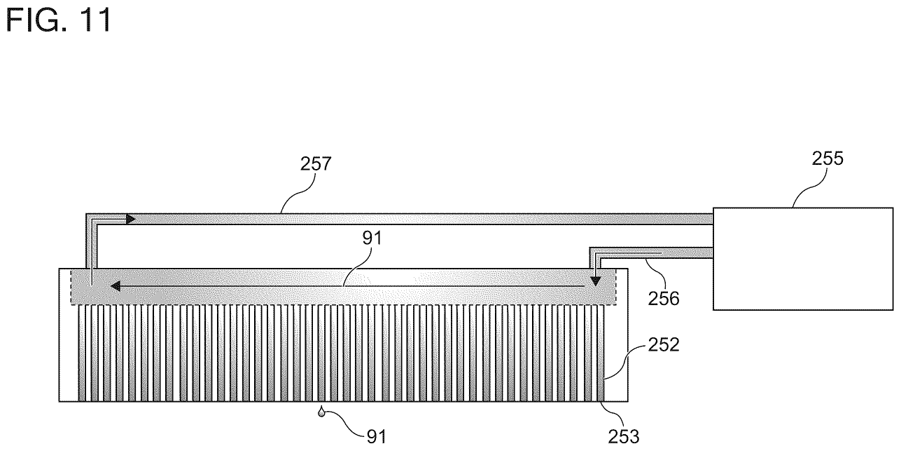

FIG. 8 and FIG. 9 are sectional views illustrating the application unit 81 in the coating module 8 according to one embodiment. FIG. 10 is a perspective view illustrating a configuration example of a nozzle where microtubes are arrayed at a narrow pitch. FIG. 11 is a sectional view illustrating the configuration example of the nozzle where the microtubes are arrayed at the narrow pitch. According to one embodiment, the nozzle 220B may include a plurality of microtubes 252 arrayed at a narrow pitch as shown in FIG. 10 and FIG. 11. For example, the nozzle 220B may be an inkjet nozzle. The nozzle 220B shown in FIG. 10 has a width L1 that is a width suitable for application of the protective film material 91 on the outer peripheral part 200 of the substrate W. In the example shown in FIG. 11, the protective film material 91 is circulated between the nozzle 220B and a supply source 255 for the protective film material 91 through a supply line 256 and a return line 257, so that the protective film material 91 in the liquid form is supplied to the plurality of microtubes 252. The protective film material 91 in the liquid form supplied to the plurality of microtubes 252 is sprayed from a plurality of discharge outlets 253 by a spray system similar to that of a general inkjet nozzle. The nozzle 220B may be controlled by the controller 5 to vary the number of and the positions of the microtubes 252 which the protective film material 91 is sprayed from. This adjusts an application range of the protective film material 91 on the substrate W.

In the configuration of FIG. 8, the nozzle 220B is placed obliquely above the outer peripheral part 200 of the substrate W. While the substrate W is rotated, the protective film material 91 is applied from the plurality of microtubes 252 of the nozzle 220B onto the outer peripheral part 200 of the substrate W.

The nozzle 220B may be moved to apply the protective film material 91. Furthermore, a plurality of the nozzles 220B may be used. For example, as shown in FIG. 9(a), the nozzles 220B may be placed on an upper side, on a lateral side and on a lower side of the outer peripheral part of the substrate W, and the protective film material 91 may be applied from these nozzles 220B onto the outer peripheral part of the substrate W. This configuration is suitable for forming the uniform protective film 90 on the entirety of the outer peripheral part of the substrate. In another example, as shown in FIG. 9(b), the nozzle 220B may be placed on the lateral side of the substrate W, and the protective film material 91 may be applied from this nozzle 220B onto the outer peripheral part of the substrate W. This configuration is suitable for application of the protective film material 91 on only part of or the entirety of the bevel portion 202 of the substrate W. In another example, as shown in FIG. 9(c), one nozzle 220B may be moved to the upper side, to the lateral side and to the lower side of the outer peripheral part of the substrate W, and the protective film material 91 may be applied from this one nozzle 220B onto the outer peripheral part of the substrate W. This configuration enables the protective film material 91 to be applied in a wide range including the edge portions 201 of the substrate W by using the small number of the nozzle 220B. In another example, as shown in FIG. 9(d), the nozzle 220B may be placed on an upper side of the substrate W, and the protective film material 91 may be sprayed from only part of the microtubes 252 of the nozzle 220B. This configuration is suitable for application of the protective film material 91 only on one single face and in a narrow range of the substrate W (only the bevel portion in the illustrated example). In another example, as shown in FIG. 9(e), the nozzle 220B may be placed obliquely above an outer side of the substrate W, and the protective film material 91 may be sprayed from only part of the microtubes 252 of the nozzle 220B to be applied only on the bevel portion on the upper face of the substrate W. In this configuration, the spray direction of the nozzle 220B relative to the curve of the bevel portion of the substrate is nearly vertical. This configuration is accordingly suitable for supplying the protective film material 91 of a more uniform thickness onto the substrate W (onto the bevel portion on the upper face of the substrate W in the illustrated example). In another example, as shown in FIG. 9(f), the protective film material 91 may be sprayed toward an outermost edge face of the substrate W from the lateral side of the substrate W and from only part of the microtubes 252 of the nozzle 220B. This configuration is suitable for application of the protective film material 91 in a narrow range only on the outermost edge face of the substrate W.

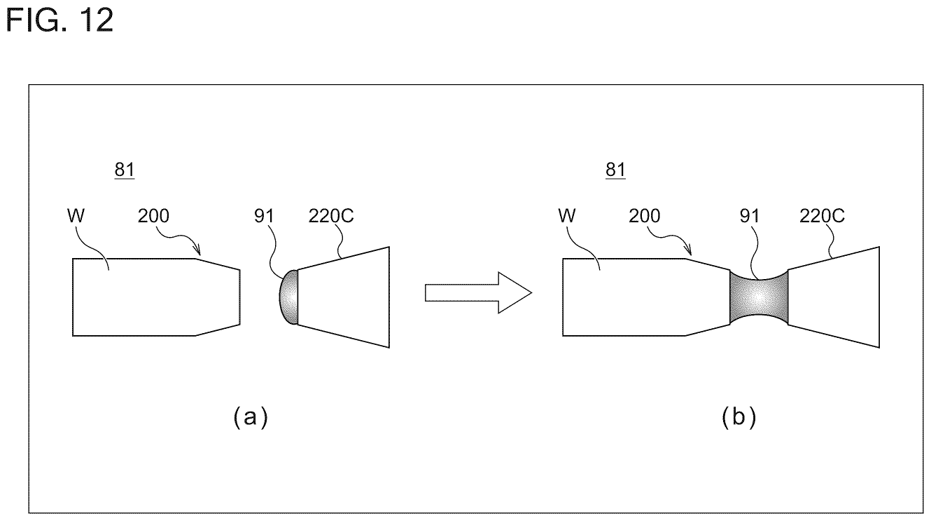

FIG. 12 is sectional views illustrating the application unit 81 in the coating module 8 according to one embodiment. In the illustrated embodiment, the protective film material 91 in the liquid form is protruded by means of the surface tension from a tip of a nozzle 220C, and the protruded protective film material 91 is brought into contact with the outer peripheral part 200 (for example, the bevel portion) of the substrate W. As shown in FIG. 12, the tip of the nozzle 220C with the protective film material 91 protruded therefrom is moved closer to the outer peripheral part 200 of the substrate W (as shown in FIG. 12(a)), and the protective film material 91 at the tip of the nozzle 220C is brought into contact with the outer peripheral part 200 of the substrate W. The tip of the nozzle 220C is subsequently moved away from the outer peripheral part 200 of the substrate W, so that the protective film material 91 is placed between the tip of the nozzle 220C and the outer peripheral part 200 of the substrate W (as shown in FIG. 12(b)). The protective film material 91 is supplied to the tip of the nozzle 220C, while the substrate W is rotated. This causes a protective film to be formed around the entire circumference of the outer peripheral part 200 (for example, the bevel portion) of the substrate W. This configuration is suitable for control of a film forming range in a narrow area of the outer peripheral part 200 of the substrate W. This configuration supplies only an amount of the protective film material 91 required for formation of the protective film 90 from the nozzle 220C and thereby reduces the amount of the protective film material 91 used.

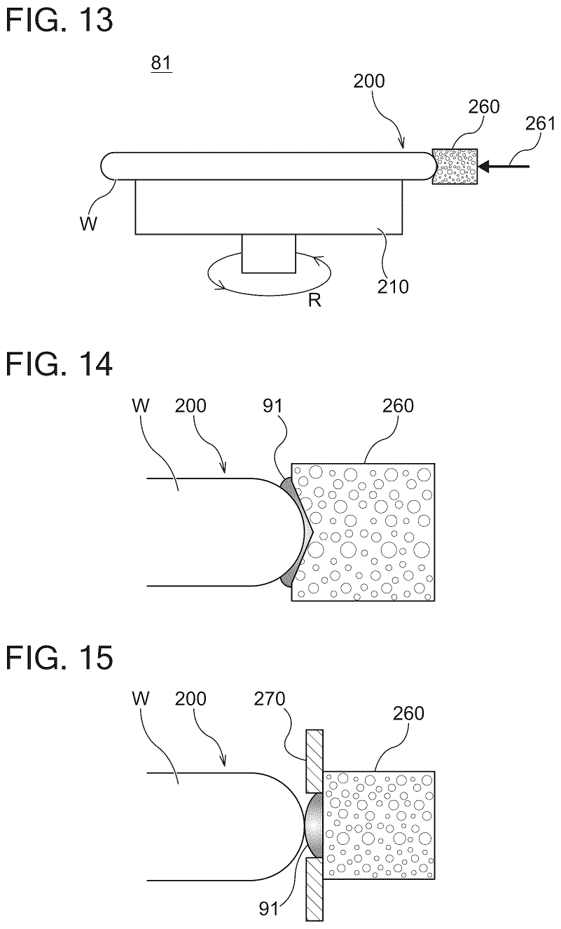

FIG. 13 is a sectional view illustrating the application unit 81 in the coating module 8 according to one embodiment. FIG. 14 is an enlarged sectional view illustrating closeup of the periphery of a porous member 260 that comes into contact with the substrate W. According to this embodiment, in place of the nozzle 220, a porous member 260 (for example, sponge) with the protective film material 91 in the liquid form sufficiently permeating therein is held by a non-illustrating moving mechanism, as shown in FIG. 13 and FIG. 14. The porous member 260 is pressed against the outer peripheral part 200 of the substrate W, so that the protective film material 91 is applied onto the outer peripheral part 200 of the substrate W. An application range of the protective film material 91 is controllable by adjusting the degree of pressing the porous member 260 against the outer peripheral part 200 of the substrate W. The porous member 260 may be pressed, for example, in a direction shown by an arrow 261 in FIG. 13. For example, the moving mechanism employed may have, for example, a configuration similar to the configuration of an air cylinder 471 shown in FIG. 23. When the porous member 260 is pressed against the outer peripheral part 200 of the substrate W, the stage 210 is rotated to rotate the substrate W in a similar manner to that described above. The protective film material 91 may be supplied to the porous member 260 in the state that the porous member 260 is pressed against the outer peripheral part 200 of the substrate W. The porous member 260 may be, for example, a sponge made of PVA.

This configuration brings the porous member 260 into contact with the substrate W, so as to apply the protective film material 91 on the substrate W and thereby controls the narrow film forming area/range with high accuracy. This configuration is accordingly suitable for control of the film forming range in the narrow area of the outer peripheral part 200 of the substrate W. Furthermore, this configuration supplies only an amount of the liquid (the protective film material 91) required for formation of the protective film from the porous member 260 and thereby reduces the amount of the protective film material 91 used.

FIG. 15 is a sectional view illustrating the principle of application in the application unit according to one embodiment. As shown in FIG. 15, the porous member 260 with the protective film material 91 in the liquid form sufficiently permeating therein may be pressurized by a pressing member 270, so that the protective film material 91 in the liquid form permeating inside of the porous member 260 may be exposed on the surface (front face) of the porous member 260. The exposure of the protective film material 91 in the liquid form on the surface of the porous member 260 herein means that a liquid droplet or a liquid layer of the protective film material 91 is formed on the surface of the porous member 260 in such a degree that the surface of the porous member 260 does not directly come into contact with the substrate W. The liquid (the protective film material 91) exposed on the surface of the porous member 260 is brought into contact with the outer peripheral part 200 (the outermost edge face in the illustrated example) of the substrate W, while the substrate W is rotated. This applies the protective film material 91 onto the outer peripheral part 200 of the substrate W, so as to form the protective film 90. A moving mechanism employed to move the porous member 260 closer to and away from the substrate W may have, for example, a configuration similar to the configuration of the air cylinder 471 shown in FIG. 23.

This configuration brings the protective film material 91 exposed on the surface of the porous member 260 into contact with the substrate W, so as to apply the protective film material 91 on the substrate W and thereby controls the narrow film forming area/range with high accuracy. Furthermore, this configuration supplies only an amount of the protective film material 91 (the liquid) required for formation of the protective film from the porous member 260 and thereby reduces the amount of the protective film material 91 used. In this configuration, the porous member 260 does not come into contact with the substrate W (non-contact). This suppresses or prevents dust emission from the substrate W and/or the porous member 260.

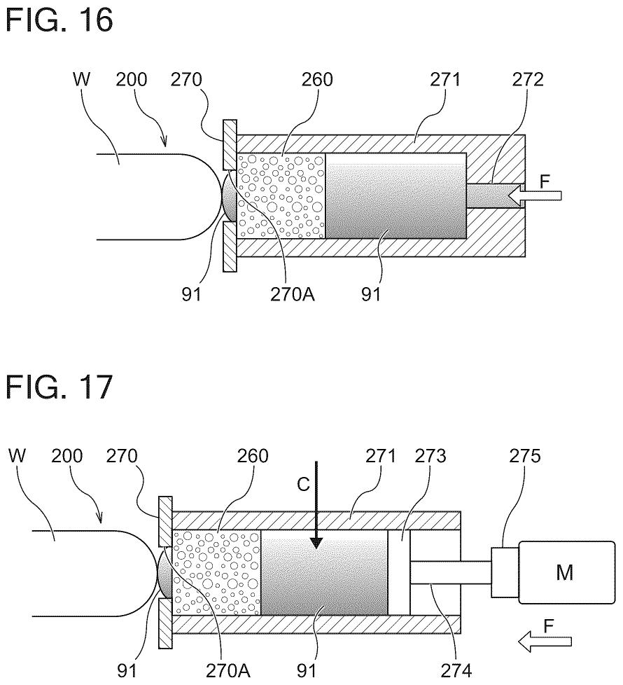

FIG. 16 is a sectional view illustrating the application unit 81 in the coating module 8 according to one embodiment. In the embodiment illustrated in FIG. 16, a porous member 260 is placed inside of a cylinder 271 or more specifically on a front side in an inner space of the cylinder 271. A pressing member 270 having an opening 270A in a central region thereof is placed on a front end face of the cylinder 271. In this configuration, the porous member 260 is pressed against the pressing member 270, so that the pressing member 270 pressurizes the porous member 260. The protective film material 91 is placed in a space on a rear side of the porous member 260 in the cylinder 271. The protective film material 91 in the liquid form pressure-fed by a pump (not shown) is supplied through a supply port 272 of the cylinder 271 to the space on the rear side of the porous member 260 in the cylinder 271. This configuration causes the protective film material 91 to be supplied to the porous member 260 and to pressurize the porous member 260 in a forward direction so as to be pressed against the pressing member 270. Pressurizing the porous member 260 causes the protective film material 91 in the liquid form permeating in the porous member 260 to be exposed on the opening 270A. The protective film material 91 exposed on the surface of the porous member 260 is brought into contact with the outer peripheral part 200 of the substrate W, while the substrate W is rotated. This applies the protective film material 91 onto the outer peripheral part 200 of the substrate W, so as to form the protective film 90. A moving mechanism employed to move the porous member 260 (the cylinder 271) closer to and away from the substrate W may have, for example, a configuration similar to the configuration of the air cylinder 471 shown in FIG. 23.

This configuration causes the protective film material 91 in the liquid form placed behind the porous member 260 to supply the protective film material 91 to the porous member 260 and to press the porous member 260 against the pressing member 270 and thereby pressurize the porous member 260. This simple configuration provides the configuration of FIG. 15 with the functions and the advantageous effects described above.

FIG. 17 is a sectional view illustrating the application unit 81 in the coating module 8 according to one embodiment. In the configuration shown in FIG. 17, instead of pressure-feeding the protective film material 91 to the rear side of the porous member 260, the protective film material 91 placed on a rear side of the porous member 260 is pressurized in a forward direction by a piston 273. The protective film material 91 is supplied from a non-illustrated supply port into a space where the protective film material 91 is placed on the rear side of the porous member 260 in a cylinder 271 (as shown by an arrow C in FIG. 17).

In the configuration of FIG. 17, a piston rod 274 of the piston 273 is connected with a motor M via a ball screw 275. A rotational motion output from the motor M is converted into a linear motion by the ball screw 275, so as to move back and forth the piston 273 in a front-rear direction. Pressurizing the protective film material 91 by the piston 273 causes the protective film material 91 to be supplied to the porous member 260 and to pressurize the porous member 260 in the forward direction so as to be pressed against the pressing member 270. Pressurizing the porous member 260 causes the protective film material 91 in the liquid form permeating in the porous member 260 to be exposed on an opening 270A. The protective film material 91 exposed on the surface of the porous member 260 is brought into contact with the outer peripheral part 200 of the substrate W, while the substrate W is rotated. This applies the protective film material 91 onto the outer peripheral part 200 of the substrate W, so as to form the protective film 90. A moving mechanism employed to move the porous member 260 (the cylinder 271) closer to and away from the substrate W may have, for example, a configuration similar to the configuration of the air cylinder 471 shown in FIG. 23.

This configuration assures the functions and the advantageous effects described above with respect to the configuration of FIG. 15. Furthermore, this configuration regulates the feed rate of the ball screw 275 to control the amount of coating of the protective film material on the substrate W. This accordingly achieves the highly accurate control of the film thickness of the protective film material.

FIG. 18 is a schematic diagram illustrating the schematic configuration of the curing unit 82 in the coating module 8. In order to cure the protective film material 91 in the liquid form after being applied on the outer peripheral part 200 of the substrate W, a heating method is employed to vaporize a solvent included in the protective film material 91. The illustrated curing unit 82 includes a heater chamber 310, a heater source 320 provided in the heater chamber 310, and a heater power source 340 configured to supply electric power to the heater source 320. The heater source 320 is configured by, for example, heating wire. The heater chamber 310 is provided with a shutter 330 configured to open and close when the substrate W is carried in and out. In the case where the application unit 81 and the curing unit 82 are separate units, after the protective film material 91 is applied on the substrate W in the coating module 8, the substrate W is transferred to the curing unit 82 to cure the protective film material 91. After the curing process of the protective film material 91, the substrate W is taken out of the curing unit 82 and is subjected to the polishing process in the polishing units 3A, 3B, 3C and/or 3D.

The curing unit 82 is not limited to the above configuration but may have another configuration including a dryer configured to supply heated or non-heated dried air, a light source configured to output light for photo-curing the protective film material or a laser configured to output laser light for curing the protective film material. The curing unit 82 may have a configuration that is a combination of two or more different types of the curing unit described above.

FIG. 19 is a schematic diagram illustrating the schematic configuration of an application/curing integral unit 8A according to one embodiment. This application/curing integral unit 8A includes a stage 210 configured to place the substrate W thereon and rotate the substrate W (omitted from the illustration of FIG. 19); a camera 280 configured to take images of the outer peripheral part 200 of the substrate W; a nozzle 220; a curing mechanism 350; and a film thickness measuring device 290. The camera 280 takes images of the outer peripheral part 200 of the substrate W. The nozzle 220 is one example of a coater and may be any type of the nozzles 220A, 220B and 220C described above. The nozzle 220B is illustrated in the embodiment of FIG. 19. The protective film material 91 may be applied by the porous member 260, in place of the nozzle 220. The curing mechanism 350 is a mechanism configured to dry and/or cure the protective film material 91 and may include a heater configured to heat the protective film material 91, a dryer configured to supply heated or non-heated dried air, a light source configured to output light for photo-curing the protective film material and/or a laser configured to output laser light for curing the protective film material. The film thickness measuring device 290 is, for example, an optical-type sensor configured to measure the film thickness of the protective film material 91 (the protective film 90) on the substrate W, based on the reflective light from the substrate W. The film thickness measuring device 290 is any sensor configured to measure the film thickness of the protective film material 91 (the protective film 90) and may be an ultrasonic sensor or any other type sensor.

In the illustrated embodiment, in order to provide a predetermined amount of coating (a predetermined thickness of coating film), the protective film material 91 is applied onto the outer peripheral part 200 of the substrate 200, while the substrate W is rotated multiple times. Prior to the application of the protective film material 91, while the substrate W is rotated, the outer edge of the substrate W is measured by using the camera 280. The spray positions of the microtubes 252 of the nozzle 220B are computed in order to achieve a predetermined application range (set by or as a distance from the outer edge of the substrate W), based on the result of the measurement, and the computed spray positions are stored in a program of the controller 5. This enables the protective film material 91 to be applied in a fixed distance from the outer edge of the substrate W (in a desired range), even when the center of the substrate W is not aligned with the center of rotation of the stage 210. After the computation of the spray positions of the microtubes 252 of the nozzle 220B, the protective film material 91 is sprayed from the microtubes 252 at the positions stored in the program, while the substrate W is rotated.

In addition to the measurement of the outer edge of the substrate W performed prior to the application, the outer peripheral edge of the substrate W (the outer peripheral edge of the substrate W including the protective film material 91) may be measured at real time, in the course of spray of the protective film material 91 from the nozzle 220. Feedback control may subsequently be performed for the spray positions of the microtubes 252 of the nozzle 220B.

The spray control from another type of nozzle 220A may be performed in a similar manner to that described above. With regard to the nozzle 220C and the porous member 260, the moving position of the nozzle 220C or the porous member 260 relative to the outer peripheral part 200 of the substrate may be controlled, based on the measurement result of the outer edge of the substrate.

Curing (drying) of the protective film material 91 is implemented by heating, hot air heating, photocuring and/or laser curing. The protective film material 91 may be either a photo-curing type or a thermal-curing type of the protective film material 91, and a curing technique according to the curing type of the protective film material is employed.

The film thickness measuring device 290 is used to measure the film thickness of the applied protective film material 91. The terminal point of application of the protective film material may be detected by using this measurement value of the film thickness.

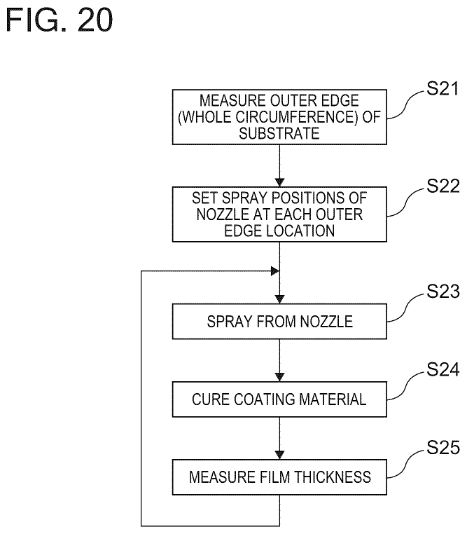

FIG. 20 is a flowchart showing a protective film forming process according to one embodiment. This process is performed by the controller 5.

At step S21, the whole circumference of the outer edge of the substrate W is measured.

At step S22, the spray positions of the nozzle 220B are set at each outer edge location in the circumferential direction of the substrate W, and the set spray positions are stored in the program of the controller 5.

At step S23, the protective film material 91 in the liquid form is sprayed from the nozzle 220B onto the outer peripheral part 200 of the substrate W.

At step S24, the protective film material 91 on the substrate W is cured by the curing mechanism 350.

At step S25, the film thickness of the protective film material 91 on the substrate W is measured by the film thickness measuring device 290. The processing of steps S23 to S25 is repeated. The protective film forming process is terminated when the film thickness of the protective film material measured by the film thickness measuring device 290 becomes equal to a set value of film thickness.

FIG. 21 is a sectional view illustrating the peeling unit 83 in the coating module 8 according to one embodiment. After polishing of the substrate W, the substrate W is transferred to the peeling unit 83 where the protective film 90 is peeled off. In the embodiment shown in FIG. 21, a porous member 460 with a peeling solution sufficiently permeated therein is pressed against the outer peripheral part 200 of the substrate W to peel off the protective film 90. The porous member 460 may be, for example, a sponge made of PVA. The peeling solution used is a peeling solution suitable for the protective film 90 (the protective film material 91). In the case of using the water-soluble protective film material 91, pure water is used as the peeling solution.

FIG. 22 is a sectional view illustrating the peeling unit 83 in the coating module 8 according to another embodiment. In the embodiment shown in FIG. 22, a peeling solution is discharged from a nozzle 420 to peel off the protective film 90. The peeling solution used is a peeling solution suitable for the protective film 90 (the protective film material 91). In the case of using the water-soluble protective film material 91, pure water is used as the peeling solution. The peeling solution may be discharged from the nozzle 420, while the nozzle 420 is moved. For example, as shown in FIG. 22, the peeling solution may be sprayed from the nozzle 420 onto the outer peripheral part 200 of the substrate W, while the nozzle 420 is moved in the vertical direction. In another example, the peeling solution may be sprayed from a plurality of nozzles 420 onto the outer peripheral part 200 of the substrate W. For example, the nozzles 420 may be provided at three different positions illustrated in FIG. 22. The nozzle 420 may be provided at four or more different positions. The peel-off of the protective film 90 may be performed immediately after polishing or after cleaning of the polished substrate. Cleaning of the substrate may be performed after the peel-off of the protective film 90.

In the case where a water-soluble material (for example, a water-soluble resin) is used as the protective film material 91, the protective film 90 may be peeled off by cleaning of the substrate in the cleaning unit, instead of providing the peeling unit 83. The polishing solution (slurry) used for polishing in the polishing unit includes the water content, so that peeling of the protective film 90 may proceed by the water content included in the polishing solution during polishing. Accordingly, a configuration that the protective film 90 is left at the end of polishing and that peel-off of the protective film 90 is completed at the end of cleaning enables peel-off of the protective film 90 to be completed during cleaning, without providing a separate peeling unit or a separate peeling process. This configuration allows for omission of the peeling process (S16) in FIG. 5.

FIG. 23 is a schematic diagram illustrating the schematic configuration of an application/curing/peeling integral unit 8B according to one embodiment. The application/curing/peeling integral unit 8B is configured by integrating the application unit 81, the curing unit 82 and the peeling unit 83 as one integral unit. In the illustrated embodiment, a peeling mechanism 830 (corresponding to the peeling unit 83) is added to the configuration of the embodiment illustrated in FIG. 19. The peeling mechanism 830 includes a porous member 460 with a peeling solution permeating therein; and an air cylinder 471 having a piston rod 474 which the porous member 460 is attached to. The air cylinder 471 moves the porous member 460 back and forth in the direction of an arrow AB, so as to bring the porous member 460 into contact with the substrate W and separate the porous member 460 from the substrate W. In the illustrated embodiment, at the time of forming the protective film, in the state that the porous member 460 with the peeling solution permeating therein is separated from the substrate W, the protective film 90 is formed on the outer peripheral part 200 of the substrate W as described above with reference to FIG. 19 and FIG. 20. When the substrate after the polishing process is carried into this unit 8B, the porous member 460 is moved forward to be pressed against the outer peripheral part 200 of the substrate W by the air cylinder 471, and the protective film 90 is peeled off from the substrate W by means of the peeling solution permeating in the porous member 460. The peeling mechanism 830 may be a peeling mechanism having a similar configuration to the configuration of the peeling mechanism of the peeling unit 83 shown in FIG. 22 or may be a peeling mechanism of any other configuration.

At least the following technical concepts are provided from the description of the above embodiments. [1] According to one aspect, there is provided a method of processing a substrate, comprising: a process of forming a protective film on an outer peripheral part of the substrate including a bevel portion, prior to a process of polishing the substrate, wherein the process of forming the protective film includes applying a protective film material in a liquid form onto the outer peripheral part of the substrate and curing the applied protective film material; and the process of polishing the substrate with the protective film formed on the outer peripheral part thereof. Curing of the protective film material includes drying by air flow, drying by heating, photocuring by light (laser or another light source) and/or air drying (natural drying). The outer peripheral part of the substrate includes an edge portion and the bevel portion. The process of forming the protective film may form the protective film on the entirety or part of the outer peripheral part of both faces or a single face of the substrate. Part of the outer peripheral part of the substrate may be, for example, part or the entirety of the edge portion, part or the entirety of the bevel portion or any other portion of the outer peripheral part. The protective film is, for example, a protective film provided for the purpose of reducing the impact caused by a physical contact to prevent chipping and prevent separation of a deposition film.

The configuration of this aspect causes the outer peripheral part of the substrate to be coated with the protective film, prior to the polishing process. The protective film accordingly works as a shock-absorbing material to suppress or prevent chipping of the substrate, which may occur when the substrate comes into contact with a retainer ring, and to suppress or prevent a fragment of the chipped substrate or chipped retainer ring from scratching the surface of the substrate in the course of the polishing process. The protective film should be formed according to each individual semiconductor manufacturing process at such a location in the outer peripheral part of the substrate that is expected to cause chipping when the substrate comes into contact with the retainer ring. The protective film may be formed on part of the outer peripheral part of the substrate or may be formed on the entirety of the outer peripheral part of the substrate.

Furthermore, this configuration applies the protective film material in the liquid form on the outer peripheral part of the substrate and cures the applied protective film material to form the protective film. This configuration accordingly enables the protective film to be formed in a desired range on the outer peripheral part of the substrate with high accuracy.

Moreover, this configuration covers an incomplete film in the outer peripheral part of the substrate with the protective film and thereby suppresses or prevents separation of the film from the substrate, which may occur when the substrate comes into contact with the retainer ring.

Additionally, using the protective film having a lower hardness than the hardness of silicon that is generally used as the material of the substrate suppresses or prevents abrasion and deficiency of the retainer ring.

Furthermore, peeling off the protective film from the substrate after the polishing process prevents the protective film from affecting the semiconductor manufacturing process after the polishing process.

[2] According to one aspect, in the method of processing the substrate, the applying the protective film material on the substrate may comprise spraying the protective film material from a nozzle onto the outer peripheral part of the substrate, so as to apply the protective film material on the substrate.

The configuration of this aspect enables the protective film to be formed on the outer peripheral part of the substrate by the simple method.

[3] According to one aspect, in the method of processing the substrate, the nozzle may comprise a nozzle having microtubes arrayed at a narrow pitch.

The configuration of this aspect enables the number of and the positions of the microcubes which the protective film material is sprayed from, to be varied and thereby enables a range of applying the protective film material on the outer peripheral part of the substrate to be adjusted with high accuracy.

[4] According to one aspect, in the method of processing the substrate, the process of forming the protective film may comprise a process of making a measurement of an outer edge of the substrate; and a process of determining a spray position of the protective film material from the nozzle onto the substrate, based on a result of the measurement.

The configuration of this aspect enables the protective film to be formed on the outer peripheral part of the substrate with high accuracy according to the shape of the outer edge of the substrate. This configuration also allows for formation of the protective film corresponding to the shape of the outer edge of the substrate attributable to an individual difference of the substrate. This configuration enables the protective film material to be applied in a fixed distance from the outer edge of the substrate (in a desired range), even when the center of the substrate is not aligned with the center of rotation of a stage.

[5] According to one aspect, in the method of processing the substrate, the process of forming the protective film may comprise a process of adjusting the spray position of the protective film material from the nozzle on the substrate, based on the result of the measurement, while the protective film material is sprayed from the nozzle.

The configuration of this aspect adjusts the spray position from the nozzle onto the substrate during the application of the protective film and thereby enables the protective film of a desired thickness to be formed on the outer peripheral part of the substrate with the higher accuracy.

[6] According to one aspect, in the method of processing the substrate, the applying the protective film material on the substrate may comprise causing the protective film material in the liquid form to be protruded from a tip of the nozzle by means of surface tension and bringing the protruded protective film material into contact with the outer peripheral part of the substrate, so as to apply the protective film material on the substrate.

The configuration of this aspect applies the protective film material by bringing the protective film material at the tip of the nozzle into contact with the outer peripheral part of the substrate and thereby assures the accurate control of a film forming area in a narrow range of the outer peripheral part of the substrate. Furthermore, this configuration causes only an amount of the protective film material required for formation of the protective film to be supplied from the nozzle and accordingly reduces the use amount of the protective film material.

[7] According to one aspect, in the method of processing the substrate, the process of forming the protective film may comprise: a process of making a measurement of an outer edge of the substrate; and a process of determining a position of the nozzle relative to the substrate, based on a result of the measurement.

The configuration of this aspect enables the protective film to be formed on the outer peripheral part of the substrate with high accuracy according to the shape of the outer edge of the substrate. This configuration also allows for formation of the protective film corresponding to the shape of the outer edge of the substrate attributable to an individual difference of the substrate.

[8] According to one aspect, in the method of processing the substrate, the process of forming the protective film may comprise a process of adjusting the position of the nozzle relative to the substrate, based on the result of the measurement, while the protective film material is applied.

The configuration of this aspect adjusts the position of the nozzle during the application of the protective film and thereby enables the protective film of a desired thickness to be formed on the outer peripheral part of the substrate with the higher accuracy.

[9] According to one aspect, in the method of processing the substrate, the applying the protective film material on the substrate may comprise bringing a porous member with the protective film material in the liquid form permeating therein, into contact with the outer peripheral part of the substrate, so as to apply the protective film material on the substrate.

The configuration of this aspect brings the porous member (for example, a sponge) into contact with the outer peripheral part of the substrate to apply the protective film material and thereby assures the accurate control of a film forming area in a narrow range of the outer peripheral part of the substrate. Furthermore, this configuration causes only an amount of the liquid (the protective film material) required for formation of the protective film to be supplied from the porous member and accordingly reduces the use amount of the protective film material.

[10] According to one aspect, in the method of processing the substrate, the applying the protective film material on the substrate may comprise pressurizing a porous member with the protective film material in the liquid form permeating therein, by means of a pressing member to make the protective film material exposed on a surface of the porous member and to bring the protective film material exposed on the surface of the porous member into contact with the outer peripheral part of the substrate, so as to apply the protective film material on the substrate.

The configuration of this aspect brings the protective film material on the surface of the porous member (for example, a sponge) into contact with the outer peripheral part of the substrate to apply the protective film material and thereby allows for control of a protective film forming area in a narrow range of the outer periphery of the substrate. Furthermore, this configuration causes only an amount of the liquid (the protective film material) required for formation of the protective film to be supplied from the porous member and accordingly reduces the use amount of the protective film material. In this configuration, the porous body does not directly come into contact with the substrate. This suppresses or prevents dust emission from the substrate and/or the porous member.

[11] According to one aspect, in the method of processing the substrate, the process of forming the protective film may comprise: a process of making a measurement of an outer edge of the substrate; and a process of determining a position of the porous member, based on a result of the measurement.

The configuration of this aspect enables the protective film to be formed on the outer peripheral part of the substrate with high accuracy according to the shape of the outer edge of the substrate. This configuration also allows for formation of the protective film corresponding to the shape of the outer edge of the substrate attributable to an individual difference of the substrate.

[12] According to one aspect, in the method of processing the substrate, the process of forming the protective film may comprise a process of adjusting the position of the porous member, based on the result of the measurement, while the porous member is brought into contact with the substrate.

The configuration of this aspect adjusts the position of the porous member during the application of the protective film and thereby enables the protective film of a desired thickness to be formed on the outer peripheral part of the substrate with the higher accuracy.

[13] According to one aspect, in the method of processing the substrate, the process of forming the protective film may comprise repeating the applying the protective film material on the substrate and the curing the applied protective film material to stack layers of the protective film material on the substrate and thereby form the protective film.

The configuration of this aspect forms the protective film by repeating application and curing of the protective film material and thereby allows for formation of the protective film of a desired thickness with the higher accuracy. This configuration also improves the reproducibility of forming the protective film of constant quality.

[14] According to one aspect, in the method of processing the substrate, the applying the protective film material may comprise making a measurement of a thickness of the protective film material on the substrate, while the protective film material is applied; and controlling the applying the protective film material, based on a result of the measurement.

Controlling the application includes controlling the position, the direction and/or the supply amount of an applicator (the nozzle or the porous member). For example, controlling the application includes controlling the position, the direction and/or the supply amount (the spray amount of the protective film material per unit time, the total spray amount) of the nozzle. In another example, controlling the application includes controlling the position, the direction and/or the supply amount (the amount of the protective film material exposed on the surface of the porous member) of the porous member.

The configuration of this aspect controls application of the protective film material, based on the result of measurement of the thickness of the protective film material or the protective film and thereby enables the protective film of a desired thickness to be formed with the higher accuracy.

[15] According to one aspect, in the method of processing the substrate, the applying the protective film material may comprise detecting a terminal point of the applying the protective film material, based on a result of the measurement, and thereby terminating the applying the protective film material.

The configuration of this aspect detects the terminal point of application of the protective film material, based on the result of measurement of the thickness of the protective film material or the protective film and thereby enables the protective film of a desired thickness to be formed with the higher accuracy.

[16] According to one aspect, in the method of processing the substrate, a material having a lower hardness than a hardness of a material of the substrate may be used as a material of the protective film.

The configuration of this aspect forms the protective film that has the lower hardness than the hardness of the substrate or that is softer than the substrate. This accordingly suppresses or prevents deficiency of a retainer ring, while the substrate is held by the retainer ring.

[17] According to one aspect, in the method of processing the substrate, a resin may be used as a material of the protective film.

The configuration of this aspect uses the resin as the material of the protective film and accordingly facilitates selection of the material of the protective film that has the lower hardness than the hardness of the material of the substrate.

[18] According to one aspect, the method of processing the substrate may further comprise a process of peeling off the protective film after the process of polishing the substrate.

The configuration of this aspect prevents the protective film from affecting a semiconductor manufacturing process after the polishing process.

[19] According to one aspect, in the method of processing the substrate, a water-soluble resin may be used as a material of the protective film.

The configuration of this aspect enables the protective film to be peeled off by using water. This accordingly enables the protective film to be readily peeled off at low cost. Additionally, a cleaning process of cleaning the substrate is generally performed after the polishing process. This configuration thus enables the protective film to be peeled off in this cleaning process and does not need to separately provide a peeling process.

[20] According to one aspect, the method of processing the substrate may further comprise a process of cleaning the substrate after the process of polishing the substrate, wherein the protective film on completion of the process of forming the protective film may have such a thickness that the protective film is left on completion of the process of polishing the substrate and that peel-off of the protective film is completed on completion of the process of cleaning the substrate.

The configuration of this aspect uses a water-soluble resin for the protective film and causes the protective film to be peeled off by using the water content included in a polishing solution (for example, a slurry) generally used in the polishing process and by using water used in the cleaning process. This configuration enables the protective film to be peeled off without extending a cleaning time and without providing a separate peeling process.

[21] According to one aspect, in the method of processing the substrate, the process of forming the protective film on the outer peripheral part of the substrate may be performed in a polishing apparatus.

The configuration of this aspect causes formation of the protective film to be performed in a neighborhood of a polishing module (polishing unit). This increases the efficiency in transfer between respective processing modules and is advantageous for enhancement of the throughput. This configuration also causes formation of the protective film and polishing to be performed in a housing of the polishing apparatus and accordingly suppresses or prevents contamination of the substrate.

[22] According to one aspect, in the method of processing the substrate, the protective film may be formed on entirety or part of the outer peripheral part of both faces or a single face of the substrate.

The configuration of this aspect causes the protective film to be formed at a location that requires protection or at a location that is expected to be sufficient for protection, according to the apparatus and the substrate. This may reduce the use amount of the protective film material in some cases.

[23] According to one aspect, there is provided an apparatus for processing a substrate, which is configured to form a protective film on an outer peripheral part of the substrate including a bevel portion. The apparatus for processing the substrate comprises an application unit having a nozzle or a porous member configured to apply a protective film material in a liquid form on an outer peripheral part of the substrate and form the protective film, prior to a process of polishing the substrate; and a polishing unit configured to polish the substrate with the protective film formed on the outer peripheral part thereof. For example, a sponge may be used as the porous member.

The configuration of this aspect exerts at least the functions and the advantageous effects described above with regard to the aspect [1].

[24] According to one aspect, the apparatus for processing the substrate may be a polishing apparatus with the application unit and the polishing unit incorporated therein.

The configuration of this aspect causes formation of the protective film to be performed in a neighborhood of a polishing module (polishing unit). This increases the efficiency in transfer between respective processing modules and is advantageous for enhancement of the throughput. This configuration also causes formation of the protective film and polishing to be performed in a housing of the polishing apparatus and accordingly suppresses or prevents contamination of the substrate.

[25] According to one aspect, in the apparatus for processing the substrate, the application unit may further include a cylinder configured to place the porous member and the protective film material therein and may be configured to pressurize the protective film material placed in the cylinder by a piston or by the protective film material that is pressure-fed by a pump into the cylinder, so as to pressurize the porous member by the protective film material placed in the cylinder.

The configuration of this aspect enables the amount of the protective film material exposed on the surface of the porous member to be readily controlled with high accuracy.

Although the embodiments of the present invention have been described based on some examples, the embodiments of the invention described above are presented to facilitate understanding of the present invention, and do not limit the present invention. The present invention can be altered and improved without departing from the subject matter of the present invention, and it is needless to say that the present invention includes equivalents thereof. In addition, it is possible to arbitrarily combine or omit respective constituent elements described in the claims and the specification in a range where at least a part of the above-mentioned problem can be solved or a range where at least a part of the effect is exhibited.

The entire disclosures of Japanese Patent No. 3,949,941 (PTL 1), Japanese Patent No. 5,982,383 (PTL 2), Japanese Unexamined Patent Publication No. 2020-021931 (PTL 3), Japanese Unexamined Patent Publication No. 2002-305201 (PTL 4), Japanese Unexamined Patent Publication No. 2007-281191 (PL 5), Japanese Unexamined Patent Publication No. 2015-188955 (PL6), and Japanese Unexamined Patent Publication No. 2009-050943 (PL7) including the specifications, claims, drawings and abstracts are incorporated herein by reference in their entireties.

### REFERENCE SIGNS LIST

1 housing
2 loading/unloading module
3 polishing module
3A-3D polishing units
4 cleaning module
8 coating module
10 polishing pad
31 top ring
32 top ring main body
33 retainer ring
41-44 cleaning units
45 drying unit
8A application/curing integral unit
8B application/curing/peeling integral unit
81 application unit
82 curing unit
83 peeling unit
90 protective film
91 protective film material
100 substrate processing apparatus
200 outer peripheral part
201 edge portion
202 bevel portion
210 stage
220 nozzle
220A nozzle
230 duct
250 nozzle
260 porous member
270 pressing member
270A opening
271 cylinder
272 supply port
273 piston
274 piston rod
275 ball screw
280 camera
310 heater chamber
320 heater source
330 shutter
340 heater power source
350 curing mechanism
290 film thickness measuring device
300 center part
410 stage
420 nozzle
460 porous member
471 cylinder
474 piston rod
W substrate

What is claimed is:

1. A method of processing a substrate, comprising:
a process of forming a protective film on an outer peripheral part of the substrate including a bevel portion, prior to a process of polishing the substrate, wherein the process of forming the protective film includes applying a protective film material in a liquid form onto the outer peripheral part of the substrate and curing the applied protective film material; and
the process of polishing the substrate with the protective film formed on the outer peripheral part thereof.

2. The method of processing the substrate according to claim 1,
wherein the applying the protective film material on the substrate comprises spraying the protective film material from a nozzle onto the outer peripheral part of the substrate, so as to apply the protective film material on the substrate.

3. The method of processing the substrate according to claim 2,
wherein the nozzle comprises a nozzle having microtubes arrayed at a narrow pitch.

4. The method of processing the substrate according to claim 2,
wherein the process of forming the protective film comprises:
a process of making a measurement of an outer edge of the substrate; and
a process of determining a spray position of the protective film material from the nozzle onto the substrate, based on a result of the measurement.

5. The method of processing the substrate according to claim 4,
wherein the process of forming the protective film comprises:
a process of adjusting the spray position of the protective film material from the nozzle on the substrate, based on the result of the measurement, while the protective film material is sprayed from the nozzle.

6. The method of processing the substrate according to claim 1,
wherein the applying the protective film material on the substrate comprises causing the protective film material in the liquid form to be protruded from a tip of the nozzle by means of surface tension and bringing the protruded protective film material into contact with the outer peripheral part of the substrate, so as to apply the protective film material on the substrate.

7. The method of processing the substrate according to claim 6,
wherein the process of forming the protective film comprises:
a process of making a measurement of an outer edge of the substrate; and
a process of determining a position of the nozzle relative to the substrate, based on a result of the measurement.

8. The method of processing the substrate according to claim 7,
wherein the process of forming the protective film comprises:
a process of adjusting the position of the nozzle relative to the substrate, based on the result of the measurement, while the protective film material is applied.

9. The method of processing the substrate according to claim 1,
wherein the applying the protective film material on the substrate comprises bringing a porous member with the protective film material in the liquid form permeating therein, into contact with the outer peripheral part of the substrate, so as to apply the protective film material on the substrate.

10. The method of processing the substrate according to claim 1,
wherein the applying the protective film material on the substrate comprises pressurizing a porous member with the protective film material in the liquid form permeating therein, by means of a pressing member to make the protective film material exposed on a surface of the porous member and to bring the protective film material exposed on the surface of the porous member into contact with the outer peripheral part of the substrate, so as to apply the protective film material on the substrate.

11. The method of processing the substrate according to claim 9,
wherein the process of forming the protective film comprises:
a process of making a measurement of an outer edge of the substrate; and
a process of determining a position of the porous member, based on a result of the measurement.

12. The method of processing the substrate according to claim 11,
wherein the process of forming the protective film comprises:
a process of adjusting the position of the porous member, based on the result of the measurement, while the porous member is brought into contact with the substrate.

13. The method of processing the substrate according to claim 1,
wherein the process of forming the protective film comprises repeating the applying the protective film material on the substrate and the curing the applied protective film material to stack layers of the protective film material on the substrate and thereby form the protective film.

14. The method of processing the substrate according to claim 1,
wherein the applying the protective film material comprises making a measurement of a thickness of the protective film material on the substrate, while the protective film material is applied; and controlling the applying the protective film material, based on a result of the measurement.

15. The method of processing the substrate according to claim 14,
wherein the applying the protective film material comprises detecting a terminal point of the applying the protective film material, based on a result of the measurement, and thereby terminating the applying the protective film material.

16. The method of processing the substrate according to claim 1,
wherein a material having a lower hardness than a hardness of a material of the substrate is used as a material of the protective film.

17. The method of processing the substrate according to claim 16,
wherein a resin is used as a material of the protective film.

18. The method of processing the substrate according to claim 1, further comprising:
a process of peeling off the protective film after the process of polishing the substrate.

19. The method of processing the substrate according to claim 1,
wherein a water-soluble resin is used as a material of the protective film.

20. The method of processing the substrate according to claim 19, further comprising:
a process of cleaning the substrate after the process of polishing the substrate,
wherein the protective film on completion of the process of forming the protective film has such a thickness that the protective film is left on completion of the process of polishing the substrate and that peel-off of the protective film is completed on completion of the process of cleaning the substrate.

21. The method of processing the substrate according to claim 1,
wherein the process of forming the protective film on the outer peripheral part of the substrate is performed in a polishing apparatus.

22. The method of processing the substrate according to claim 1,
wherein the protective film is formed on entirety or part of the outer peripheral part of both faces or a single face of the substrate.

23. An apparatus for processing a substrate, which is configured to form a protective film on an outer peripheral part of the substrate including a bevel portion, the apparatus comprising:
an application unit having a nozzle or a porous member configured to apply a protective film material in a liquid form on an outer peripheral part of the substrate and form the protective film, prior to a process of polishing the substrate; and
a polishing unit configured to polish the substrate with the protective film formed on the outer peripheral part thereof.

24. The apparatus for processing the substrate according to claim 23,
the apparatus for processing the substrate is a polishing apparatus with the application unit and the polishing unit incorporated therein.

25. The apparatus for processing the substrate according to claim 23,
wherein the application unit further includes a cylinder configured to place the porous member and the protective film material therein, and
wherein the application unit is configured to pressurize the protective film material placed in the cylinder by a piston or by the protective film material that is pressure-fed by a pump into the cylinder, so as to pressurize the porous member by the protective film material placed in the cylinder.
